(19) United States
(12) Patent Application Publication
(10) Pub. No.: US 2026/0047099 A1
(43) Pub. Date: Feb. 12, 2026

(54) SEMICONDUCTOR DEVICE INCLUDING FERROELECTRIC MEMORY STRUCTURE AND CONTROL TRANSISTOR AND METHOD OF DRIVING SEMICONDUCTOR DEVICE

(71) Applicant: SK hynix Inc., Gyeonggi-do (KR)

(72) Inventor: Jung Wook WOO, Gyeonggi-do (KR)

(21) Appl. No.: 19/000,708

(22) Filed: Dec. 24, 2024

(30) Foreign Application Priority Data
Aug. 7, 2024 (KR) 10-2024-0105756

(51) Int. Cl. H10B 53/30; G11C 11/22

(52) U.S. Cl. CPC H10B 53/30; G11C 11/221; G11C 11/2259; G11C 11/2275

(57) ABSTRACT

A semiconductor device according to an embodiment of the present disclosure includes a ferroelectric memory structure, a control transistor, and a control connection structure that electrically connects the control transistor with the ferroelectric memory structure. The ferroelectric memory structure includes a switching gate dielectric layer, a switching gate electrode layer, and a first memory electrode layer, a ferroelectric memory layer, and a second memory electrode layer, the first memory electrode layer being connected to the switching gate electrode layer. The control transistor structure includes a control source electrode and a control drain electrode, a control gate dielectric layer and a control gate electrode layer. The control connection structure electrically connects the control drain electrode and the switching gate electrode layer to each other over the substrate.

### CROSS-REFERENCE TO RELATED APPLICATIONS

The present application claims priority under 35 U.S.C. 119(a) to Korean Application No. 10-2024-0105756, filed on Aug. 7, 2024, which is incorporated herein by reference in its entirety.

### BACKGROUND

### 1. Technical Field

Embodiments of the present disclosure generally relate to a semiconductor device and a method of driving the semiconductor device, and more particularly, to a semiconductor device including a ferroelectric memory structure and a control transistor and a method of driving the semiconductor device.

### 2. Related Art

In general, a ferroelectric material refers to a material that has spontaneous electrical polarization when no external electric field is applied. In addition, the electrical polarization can exhibit hysteresis behavior when the external electric field is applied. Accordingly, by controlling the external electric field applied to the ferroelectric material, polarization states having various magnitudes and orientations following the hysteresis behavior can be reversibly implemented within the ferroelectric material. Moreover, the polarization can be preserved within the ferroelectric material in the form of remanent polarization after the external electric field is removed.

Recently, ferroelectric memory devices that utilize the polarization of the ferroelectric material as signal information have appeared. As an example, a ferroelectric capacitor having a capacitor dielectric layer of the ferroelectric material and a ferroelectric field effect transistor having a gate dielectric layer of the ferroelectric material are being developed as the ferroelectric memory devices.

### SUMMARY

A semiconductor device according to an embodiment of the present disclosure may include a ferroelectric memory structure, a control transistor structure, and a control connection structure that electrically connects the control transistor with the ferroelectric memory structure. The ferroelectric memory structure may include a switching gate dielectric layer disposed on a substrate, a switching gate electrode layer disposed on the switching gate dielectric layer, and a first memory electrode layer, a ferroelectric memory layer, and a second memory electrode layer that are disposed over the switching gate electrode layer, the first memory electrode layer being connected to the switching gate electrode layer. The control transistor structure may include a control source electrode and a control drain electrode that are disposed in the substrate, and spaced apart from each other, and a control gate dielectric layer and a control gate electrode layer that are disposed on a first region of the substrate, the first region located between the control source electrode and the control drain electrode. The control connection structure electrically connects the control drain electrode and the switching gate electrode layer to each other over the substrate.

A semiconductor device according to another embodiment of the present disclosure may include a ferroelectric memory structure disposed over a substrate, and a control transistor structure and a selection transistor structure that are disposed on the substrate and electrically connected to the ferroelectric memory structure. The ferroelectric memory structure may include a switching gate dielectric layer disposed on the substrate, a switching gate electrode layer disposed on the switching gate dielectric layer, and a first memory electrode layer, a ferroelectric memory layer, and a second memory electrode layer that are disposed over the switching gate electrode layer, the first memory electrode layer being electrically connected to the switching gate electrode layer. The control transistor structure may include a control drain electrode electrically connected to the switching gate electrode layer and a control source electrode receiving a control voltage. The selection transistor structure may include a selection drain electrode electrically connected to the second memory electrode layer and a selection source electrode receiving a selection voltage. The control transistor may be configured to be electrically turned on while the selection transistor is turned off, and the selection transistor may be configured to be electrically turned on while the control transistor is turned off.

In a method of driving a semiconductor device according to further another embodiment of the present disclosure, a semiconductor device including a ferroelectric memory structure may be prepared. The ferroelectric memory structure may include a switching gate dielectric layer disposed on a substrate, a switching gate electrode layer disposed on the switching gate dielectric layer, a first memory electrode layer, a ferroelectric memory layer disposed over the switching gate electrode layer, and a second memory electrode layer disposed on the first memory electrode layer. The first memory electrode layer may be electrically connected to the switching gate electrode layer. The switching gate electrode layer may be electrically connected to a discharge bias terminal, the substrate may be electrically connected to a substrate bias terminal, and the second memory electrode layer may be electrically connected to a memory bias terminal. The discharge bias terminal is electrically floated to electrically float the switching gate electrode layer. A program voltage may be applied to the memory bias terminal to write polarization in the ferroelectric memory layer.

### BRIEF DESCRIPTION OF THE DRAWINGS

FIG. 1A is a schematic diagram illustrating a ferroelectric field effect transistor according to a first comparative example of the present disclosure.

FIG. 1B is a schematic structural diagram of the ferroelectric field effect transistor in FIG. 1A.

FIG. 1C is a circuit diagram illustrating a combination of capacitors formed within the ferroelectric field effect transistor in FIG. 1A.

FIG. 2A is a schematic diagram illustrating a ferroelectric metal field effect transistor according to a second comparative example of the present disclosure.

FIG. 2B is a schematic structural diagram of the ferroelectric metal field effect transistor in FIG. 2A.

FIG. 2C is a circuit diagram illustrating a combination of capacitors formed within the ferroelectric metal field effect transistor in FIG. 2A.

FIG. 3 is a schematic circuit diagram illustrating a semiconductor device according to an embodiment of the present disclosure.

FIG. 4 is a cross-sectional view of a semiconductor device according to an embodiment of the present disclosure.

FIG. 5 is a schematic diagram illustrating a program operation of a semiconductor device according to an embodiment of the present disclosure.

FIG. 6 is a schematic flowchart illustrating a program operation of a semiconductor device according to an embodiment of the present disclosure.

FIG. 7 is a schematic diagram illustrating an erase operation of a semiconductor device according to an embodiment of the present disclosure.

FIG. 8 a schematic flowchart illustrating an erase operation of a semiconductor device according to an embodiment of the present disclosure.

FIG. 9 is a schematic diagram illustrating a discharge operation of a semiconductor device according to an embodiment of the present disclosure.

FIG. 10 is a schematic flowchart illustrating a discharge operation of a semiconductor device according to an embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or custom of a user or operator in the technical field. The meanings of the terms used follow the definitions defined when specifically defined herein, and may be interpreted as meanings generally recognized by those skilled in the art in the absence of specific definitions.

In addition, in describing a method or a fabricating method, each process constituting the method may be performed in a different order from the stated order unless a specific order is clearly stated in the context. That is, the processes may proceed in the same order as stated, may proceed substantially simultaneously, or may proceed in the opposite order.

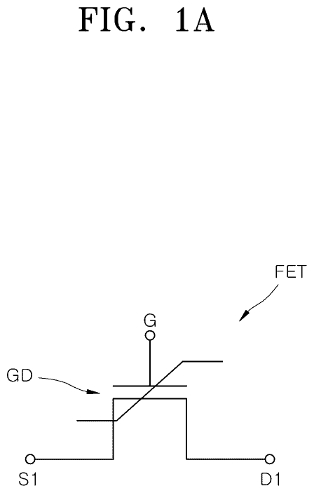

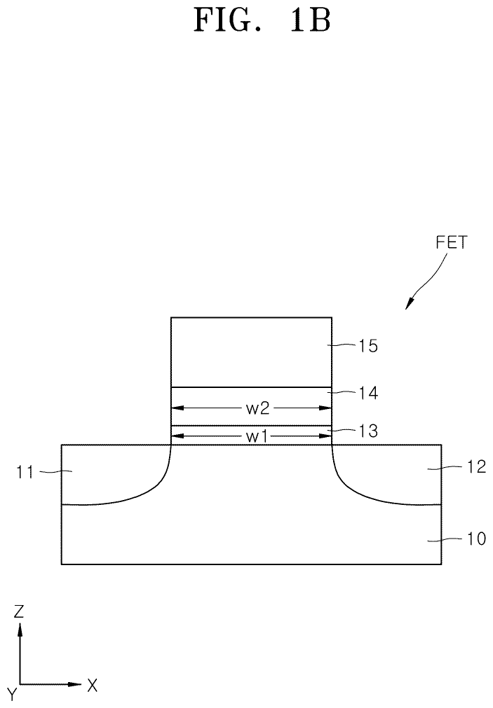

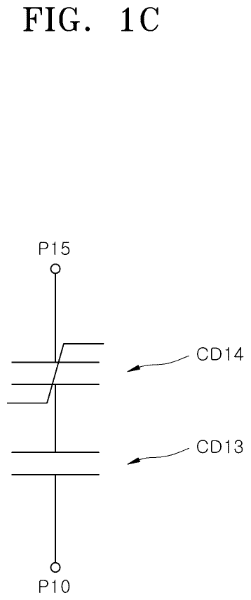

FIG. 1A schematically illustrates a ferroelectric field effect transistor according to a first comparative example of the present disclosure. FIG. 1B is a schematic structural diagram of the ferroelectric field effect transistor in FIG. 1A. FIG. 1C is a circuit diagram illustrating a combination of capacitors formed within the ferroelectric field effect transistor in FIG. 1A.

Referring to FIG. 1A, a ferroelectric field effect transistor FET includes a source electrode S1, a drain electrode D1, a gate ferroelectric layer GD, and a gate electrode G. In the ferroelectric field effect transistor FET, a program voltage or an erase voltage is applied to the gate electrode G to form polarization having a predetermined orientation within the gate ferroelectric layer GD. The polarization may be maintained in the gate ferroelectric layer GD as remanent polarization having the same orientation even after the program voltage or the erase voltage is removed. The magnitude of a channel threshold voltage of the ferroelectric field effect transistor FET is changed depending on the orientation of the remanent polarization, so that the remanent polarization can be used as signal information.

Referring to FIG. 1B, the ferroelectric field effect transistor FET includes a source region 11 and a drain region 12 that are disposed in a substrate 10 spaced apart from each other. The substrate 10 may be formed of a semiconductor material doped with an n-type or p-type dopant. The source region 11 and the drain region 12 may be regions of the substrate 10, which are doped with a dopant of a type different from the doping type of the substrate 10.

The ferroelectric field effect transistor FET includes a gate dielectric layer 13, a ferroelectric layer 14, and a gate electrode layer 15 that are sequentially disposed on a region of the substrate 10, located between the source region 11 and the drain region 12.

The structure in which the gate dielectric layer 13 and the ferroelectric layer 14 are stacked may correspond to the gate ferroelectric layer GD in FIG. 1A. The remanent polarization, which is signal information, may be non-volatilely preserved in the ferroelectric layer 14. The gate dielectric layer 13 may play a role of a buffer layer between the substrate 10 and the ferroelectric layer 14. The gate dielectric layer 13 may include a non-ferroelectric material. Accordingly, the gate dielectric layer 13 might not have the remanent polarization. As an example, the gate dielectric layer 13 may include oxide, nitride, oxynitride, or the like.

In an embodiment, a dielectric constant of the ferroelectric layer 14 may be greater than the dielectric constant of the gate dielectric layer 13. When the gate dielectric layer 13 includes silicon oxide and the ferroelectric layer 14 includes hafnium oxide, the dielectric constant of the gate dielectric layer 13 may be about 3.7, and the dielectric constant of the ferroelectric layer 14 may be about 25.

In the ferroelectric field effect transistor FET, the gate dielectric layer 13 and the ferroelectric layer 14 overlap with each other in a z-direction. For example, the gate dielectric layer 13 has a width w1 along an x-direction, and the ferroelectric layer 14 has a width w2 along the x-direction. The width w1 of the gate dielectric layer 13 may be substantially the same as the width w2 of the ferroelectric layer 14.

Referring to FIG. 1C, the gate dielectric layer 13 and the ferroelectric layer 14 in FIG. 1B may form a non-ferroelectric capacitor CD13 and a ferroelectric capacitor CD14 that are connected in series between a substrate terminal P10 and a gate electrode terminal P15, respectively. When a predetermined voltage V is applied between the substrate terminal P10 and the gate electrode terminal P15, the amount Q of charges charged in each of the non-ferroelectric capacitor CD13 and the ferroelectric capacitor CD14 may be the same.

Accordingly, the following Equation (1) can be established.

C₁₃V₁₃ =C₁₄V₁₄ (1)

In Equation (1), C₁₃ is the capacitance of the non-ferroelectric capacitor CD13, C₁₄ is the capacitance of the ferroelectric capacitor CD14, V₁₃ is the voltage distributed to the non-ferroelectric capacitor CD13 by the applied voltage V, and V₁₄ is the voltage distributed to the ferroelectric capacitor CD14 by the applied voltage V.

The Equation (1) may be converted into Equation (2) below.

C₁₄/C₁₃=V₁₃/V₁₄ (2)

As described above, because the dielectric constant of the ferroelectric layer 14 is greater than the dielectric constant of the gate dielectric layer 13 and the ferroelectric layer 14 and the gate dielectric layer 13 overlap with each other in the z-direction, the capacitance C₁₄ of the ferroelectric capacitor CD14 may be greater than the capacitance C₁₃ of the non-ferroelectric capacitor CD13. Accordingly, the voltage V₁₃ distributed to the non-ferroelectric capacitor CD13 may be greater than the voltage V₁₄ distributed to the ferroelectric capacitor CD14.

According to the Equation (2), as the ratio C₁₄/C₁₃ increases, the ratio V₁₃/V₁₄ may also increase. As a result, when the program operation and erase operation of the ferroelectric field effect transistor FET in FIG. 1B are performed repeatedly, the possibility of destruction of the gate dielectric layer 13 between the gate dielectric layer 13 and the ferroelectric layer 14 may increase. Accordingly, the operation reliability of the ferroelectric field effect transistor FET due to destruction of the gate dielectric layer 13 may deteriorate.

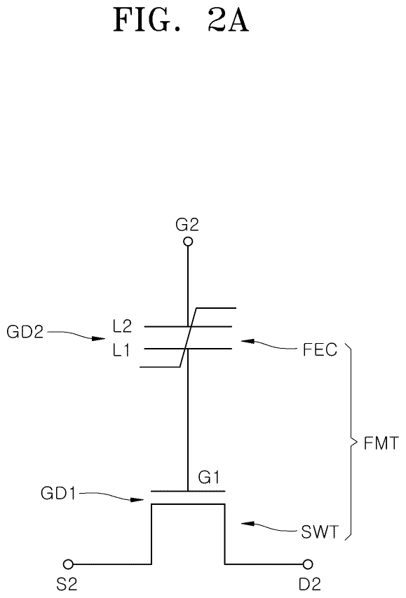

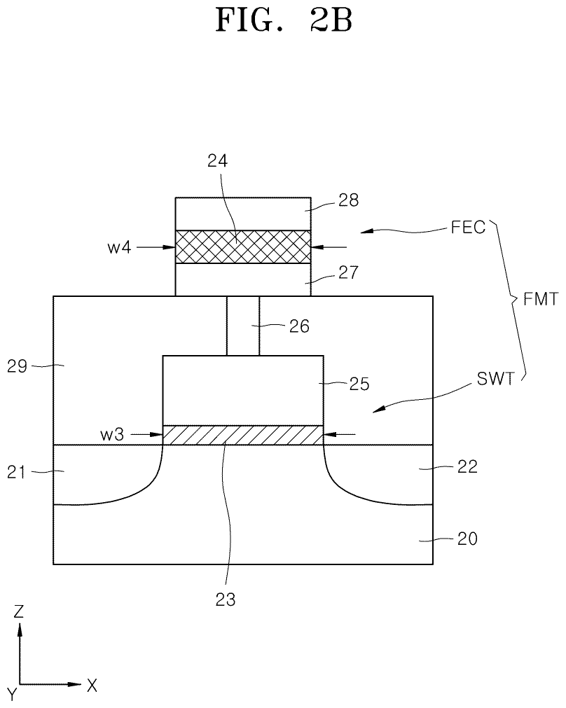

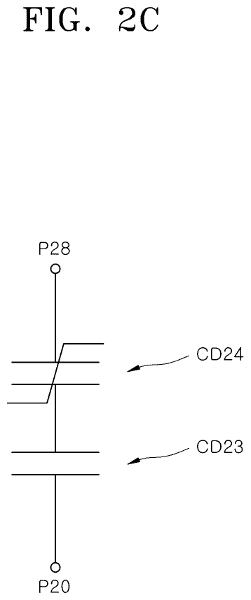

FIG. 2A schematically illustrates a ferroelectric metal field effect transistor according to a second comparative example of the present disclosure. FIG. 2B is a schematic structural diagram of the ferroelectric metal field effect transistor in FIG. 2A. FIG. 2C is a circuit diagram illustrating a combination of capacitors formed within the ferroelectric metal field effect transistor in FIG. 2A.

Referring to FIG. 2A, a ferroelectric metal field effect transistor FMT includes a switching transistor SWT and a ferroelectric capacitor FEC that are electrically connected to each other. The switching transistor SWT includes a source electrode S2, a drain electrode D2, a gate dielectric layer GD1, and a gate electrode G1. The gate dielectric layer GD1 may be a non-ferroelectric layer. The ferroelectric capacitor FEC includes a first electrode L1 electrically connected to the gate electrode G1 of the switching transistor SWT, a second electrode L2 disposed spaced apart from the first electrode L1, and a ferroelectric layer GD2 disposed between the first electrode L1 and the second electrode L2. The second electrode L2 may be connected to a driving voltage application terminal G2.

A program operation or an erase operation of the ferroelectric metal field effect transistor FMT may be performed by applying a program voltage or an erase voltage to the driving voltage application terminal G2 to form polarization having a predetermined orientation within the ferroelectric layer GD2 of the ferroelectric capacitor FEC. The polarization may exist in the ferroelectric layer GD2 as remanent polarization having the same orientation even after the program voltage or the erase voltage is removed. Because a magnitude of a channel threshold voltage of the switching transistor SWT changes depending on the orientation of the remanent polarization, the remanent polarization can be utilized as signal information.

Referring to FIG. 2B, the switching transistor SWT includes a source region 21 and a drain region 22 that are disposed in a substrate 20 spaced apart from each other. The substrate 20, the source region 21, and the drain region 22 may be the same as the substrate 10, the source region 11, and the drain region 12 described above with reference to FIG. 1.

The switching transistor SWT includes a gate dielectric layer 23 and a gate electrode layer 25 that are sequentially disposed over a region of the substrate 20, located between the source region 21 and the drain region 22. The gate dielectric layer 23 may correspond to the gate dielectric layer GD1 in FIG. 2A. The gate dielectric layer 23 may include a non-ferroelectric material. As an example, the gate dielectric layer 23 may include oxide, nitride, oxynitride, or the like. The gate dielectric layer 23 may have a width w3 of a predetermined size along the x-direction.

The ferroelectric capacitor FEC includes a first electrode layer 27 disposed over the gate electrode layer 25, a ferroelectric layer 24 disposed on the first electrode layer 27, and a second electrode layer 28 disposed on the ferroelectric layer 24. The ferroelectric layer 24 may have remanent polarization, which is signal information. The dielectric constant of the ferroelectric layer 24 may be greater than the dielectric constant of the gate dielectric layer 23. The ferroelectric layer 24 may have a predetermined width w4 along the x-direction.

A conductive via 26 connected to the first electrode layer 27 is disposed on the gate electrode layer 25. The gate electrode layer 25 and the first electrode layer 27 are disposed spaced apart from each other in the z-direction with the conductive via 26 therebetween.

In the ferroelectric metal field effect transistor FMT in FIG. 2B, the gate dielectric layer 23 and the ferroelectric layer 24 are disposed spaced apart from each other, compared to the ferroelectric field effect transistor FET in FIG. 2A. In addition, the width w3 of the gate dielectric layer 23 and the width w4 of the ferroelectric layer 24 may be controlled to be different from each other. As illustrated, the width w3 of the gate dielectric layer 23 may be greater than the width w4 of the ferroelectric layer 24.

Referring to FIG. 2C, the gate dielectric layer 23 and the ferroelectric layer 24 in FIG. 2B may form a non-ferroelectric capacitor CD23 and a ferroelectric capacitor CD24 that are connected in series between a substrate terminal P20 and a driving voltage application terminal P28. When a predetermined voltage V is applied between the substrate terminal P20 and the driving voltage application terminal P28, the amount Q of charge charged in each of the non-ferroelectric capacitor CD23 and the ferroelectric capacitor CD24 may be the same. Accordingly, the following Equation (3) may be established.

C₂₄/C₂₃=V₂₃/V₂₄ (3)

In Equation (3), C₂₃ is the capacitance of the non-ferroelectric capacitor CD23, C₂₄ is the capacitance of the ferroelectric capacitor CD24, V₂₃ is the voltage distributed by the applied voltage V to the non-ferroelectric capacitor CD23, and V₂₄ is the voltage distributed by the applied voltage V to the ferroelectric capacitor CD24.

Referring to FIG. 2B, the width w3 of the gate dielectric layer 23 of the non-ferroelectric capacitor CD23 and the width w4 of the ferroelectric layer 24 of the ferroelectric capacitor CD24 can be controlled through the manufacturing process, thereby controlling the surface areas of the gate dielectric layer 23 and the ferroelectric layer 24. As shown in Equation (4) below, the capacitance C of a capacitor including a pair of electrodes and a dielectric layer disposed between the pair of electrodes is proportional to the dielectric constant εᵣ and the surface area A of the capacitor dielectric layer.

C=εₒ*εᵣ*A/d (4)

In Equation (4), εₒ is the permittivity of vacuum, εᵣ is the dielectric constant, A is the surface area of the dielectric layer overlapping the pair of electrodes, and d is the distance between the pair of electrodes.

In the ferroelectric metal field effect transistor FMT in FIG. 2A through FIG. 2C, the surface area of each of the gate dielectric layer 23 and the ferroelectric layer 24 can be controlled to change the ratio C₂₄/C₂₃ and the ratio V₂₃/V₂₄ in Equation (3). As an example, when a predetermined driving voltage V is applied between the substrate terminal P20 and the driving voltage application terminal P28, the magnitude of the voltage distributed to the non-ferroelectric capacitor CD23 among the non-ferroelectric capacitor CD23 and the ferroelectric capacitor CD24 can be reduced by decreasing the ratio C₂₄/C₂₃. As a result, compared to the ferroelectric field effect transistor FET in FIG. 1A through FIG. 1C, when the program operations and erase operations are repeatedly performed, the voltage distributed to the gate dielectric layer 23 in FIG. 2B can be relatively reduced, thereby improving the breakdown characteristics of the gate dielectric layer 23. In this case, because the magnitude of the voltage distributed to the ferroelectric capacitor CD24 increases relatively, a margin for the range of the driving voltage V can be secured, compared to the ferroelectric field effect transistor FET in FIG. 1A through FIG. 1C. As an example, in the case of the ferroelectric metal field effect transistor FMT, the program operation and the erase operation can be performed at a relatively lower driving voltage, compared to the case of the ferroelectric field effect transistor FET.

Referring to FIG. 2B, in the case of the ferroelectric metal field effect transistor FMT, the gate electrode layer 25 can be maintained in an electrically floating state in a standby state. After the program operation and the erase operation are completed, when a portion of electrons charged in the ferroelectric layer 24 of the ferroelectric capacitor FEC leaks to the gate electrode layer 25, the leaked electrons can be charged in the gate electrode layer 25 in the electrically floating state. The electrons charged in the gate electrode layer 25 can change the potential of the gate electrode layer 25, thereby changing the channel threshold voltage of the switching transistor SWT. As a result, the electrons charged in the gate electrode layer 25 in the electrically floating state may lower the reliability of the program operation and erase operation of the ferroelectric metal field effect transistor FMT.

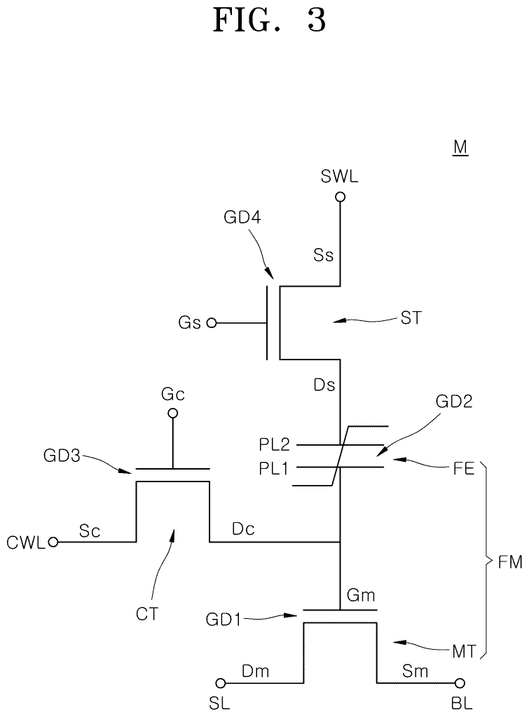

FIG. 3 is a schematic circuit diagram illustrating a semiconductor device according to an embodiment of the present disclosure. Referring to FIG. 3, a semiconductor device M includes a ferroelectric memory element FM and a control transistor CT. The ferroelectric memory element FM includes a switching transistor MT and a ferroelectric capacitor FE. In an embodiment, the ferroelectric memory element FM may be a ferroelectric metal field effect transistor. The control transistor CT is electrically connected to a switching gate electrode Gm of the switching transistor MT. In an embodiment, the semiconductor device M further includes a selection transistor ST electrically connected to the ferroelectric capacitor FE.

Referring to FIG. 3, the switching transistor MT includes a switching source electrode Sm, a switching drain electrode Dm, a switching gate dielectric layer GD1, and the switching gate electrode Gm. The switching gate dielectric layer GD1 may be a non-ferroelectric layer. The switching source electrode Sm is connected to a bit line BL. The switching drain electrode Dm is connected to a source line SL.

The ferroelectric capacitor FE includes a first memory electrode PL1 electrically connected to the switching gate electrode Gm of the switching transistor MT, a second memory electrode PL2 disposed spaced apart from the first memory electrode PL1, and a ferroelectric layer GD2 disposed between the first memory electrode PL1 and the second memory electrode PL2. The ferroelectric layer GD2 may retain remanent polarization of different orientations as signal information.

The control transistor CT includes a control source electrode Sc, a control drain electrode Dc, a control gate dielectric layer GD3, and a control gate electrode Gc. The control gate dielectric layer GD3 may be a non-ferroelectric layer. The control drain electrode Dc is electrically connected to the switching gate electrode Gm of the switching transistor MT. The control source electrode Sc is electrically connected to a control word line CWL.

The selection transistor ST includes a selection source electrode Ss, a selection drain electrode Ds, a selection gate dielectric layer GD4, and a selection gate electrode Gs. The selection gate dielectric layer GD4 may be a non-ferroelectric layer. The selection drain electrode Ds is electrically connected to the second memory electrode PL2 of the ferroelectric capacitor FE. The selection source electrode Ss is electrically connected to a selection word line SWL.

In an embodiment, the program operation of the semiconductor device M may proceed as follows. The control transistor CT is turned off. The control transistor CT may be turned off by applying a gate voltage lower than a predetermined threshold voltage to the control gate electrode Gc. The selection transistor ST is turned on while the control transistor CT is turned off. The selection transistor ST may be turned on by applying a gate voltage equal to or higher than the predetermined threshold voltage to the selection gate electrode Gs. In this case, at least one of the switching source electrode Sm and the switching drain electrode Dm of the switching transistor MT may be grounded. Alternatively, a ground voltage may be applied as a back bias to the substrate of the switching transistor MT.

As the selection transistor ST is turned on, the selection word line SWL may apply a program voltage to the ferroelectric memory element FM. The program voltage may write first polarization of a predetermined orientation to the ferroelectric layer GD2 of the ferroelectric capacitor FE. Because the control transistor CT is in the turned-off state, when the program voltage is applied, the switching gate electrode Gm may maintain an electrically floating state. Thereafter, the program voltage applied to the selection gate electrode Gs may be removed to turn off the selection transistor ST. As the selection transistor ST is turned off, the program voltage applied to the ferroelectric memory element FM may be removed. After the program voltage is removed, the ferroelectric layer GD2 may retain the first remanent polarization having the same orientation as the first polarization as first signal information.

In an embodiment, the erase operation of the semiconductor device M may proceed as followed. While the control transistor CT is in the turned-off state, a gate voltage equal to or higher than the predetermined threshold voltage is applied to the selection gate electrode Gs to turn on the selection transistor ST. In this case, at least one of the switching source electrode Sm and the switching drain electrode Dm of the switching transistor MT may be grounded. Alternatively, a ground voltage may be applied as a back bias to the substrate of the switching transistor MT.

As the selection transistor ST is turned on, the selection word line SWL may apply an erase voltage to the ferroelectric memory element FM. The polarity of the erase voltage may be opposite to the polarity of the program voltage. The erase voltage may write second polarization of a predetermined orientation to the ferroelectric layer GD2 of the ferroelectric capacitor FE. The second polarization may have the orientation opposite to the orientation of the first polarization. Because the control transistor CT is in the turned-off state, the switching gate electrode Gm may be maintained in the electrically floating state when the erase voltage is applied. Thereafter, the erase voltage applied to the selection gate electrode Gs may be removed to turn off the selection transistor ST. As the selection transistor ST is turned off, the erase voltage applied to the ferroelectric memory element FM may be removed. After the erase voltage is removed, the ferroelectric layer GD2 may retain second remanent polarization having the same orientation as the second polarization as second signal information.

In an embodiment, a read operation for the semiconductor device M may be performed as follows. While the control transistor CT is in the turned-off state, a gate voltage equal to or higher than the predetermined threshold voltage is applied to the selection gate electrode Gs to turn on the selection transistor ST. As the selection transistor ST is turned on, the selection word line SWL may apply a read voltage to the ferroelectric memory element FM. The read voltage might not switch the orientation of the remanent polarization stored in the ferroelectric layer GD2. As an example, the polarity of the read voltage may be the same as the polarity of the program voltage, and the magnitude of the read voltage may be less than the magnitude of the program voltage.

Next, an operation voltage is applied between the switching source electrode Sm and the switching drain electrode Dm, and the channel current of the switching transistor MT is measured to read a channel threshold voltage. Because the magnitude of the channel threshold voltage changes depending on the first remanent polarization and the second remanent polarization, the first signal information and the second signal information can be distinguished from each other using the channel threshold voltage.

As described above, during the program operation and erase operation, the switching gate electrode Gm may be maintained in an electrically floating state. When the switching gate electrode Gm is maintained in the electrically floating state, the electrons that inevitably leak from the ferroelectric layer GD2 of the ferroelectric capacitor FE may be charged in the switching gate electrode Gm. The electrons charged in the switching gate electrode Gm may change the potential of the switching gate electrode Gm, thereby unintentionally changing the channel threshold voltage of the switching transistor MT.

According to an embodiment of the present disclosure, the electrons charged in the switching gate electrode Gm can be removed by performing a discharge operation using the control transistor CT. The discharge operation may be performed as follows.

The selection transistor ST is turned off. The control transistor CT may be turned on by applying a gate voltage equal to or higher than the predetermined threshold voltage to the control gate electrode Gc while the selection transistor ST is turned off. In this case, at least one of the switching source electrode Sm and the switching drain electrode Dm of the switching transistor MT may be grounded. Alternatively, a ground voltage may be applied as a back bias to the substrate of the switching transistor MT.

As the control transistor CT is turned on, the control word line CWL may apply a discharge voltage to the switching transistor MT. In an embodiment, the polarity of the discharge voltage may be the same as the polarity of the erase voltage.

The discharge voltage may discharge the electrons charged in the switching gate electrode Gm to the substrate of the switching transistor MT. As an example, when the discharge voltage having a negative polarity is applied, the electrons charged in the switching gate electrode Gm may tunnel through the switching gate dielectric layer GD1 and move to the substrate.

As described above, the electrons charged in the floating switching gate electrode Gm can be removed by performing the discharge operation using the control transistor CT. As a result, the potential of the switching gate electrode Gm can be maintained at a constant level, and the reliability of the channel threshold voltage can be maintained while the program operations and erase operations of the ferroelectric memory element FM are repeated.

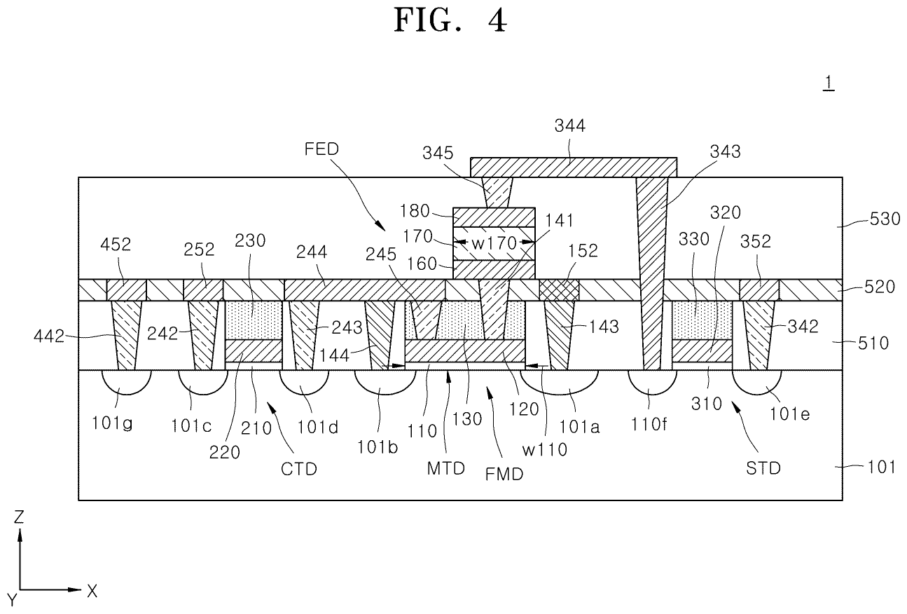

FIG. 4 is a cross-sectional view of a semiconductor device according to an embodiment of the present disclosure. The semiconductor device in FIG. 4 may correspond to the semiconductor device M in FIG. 3.

Referring to FIG. 4, a semiconductor device 1 includes a ferroelectric memory structure FMD, a control transistor structure CTD, and a control connection structure that electrically connects the control transistor CTD with the ferroelectric memory structure FMD. The ferroelectric memory structure FMD includes a switching transistor structure MTD and a ferroelectric capacitor structure FED. In addition, the semiconductor device 1 further includes a selection transistor structure STD electrically connected to the ferroelectric memory structure FMD on the substrate 101.

A substrate 101 may include a semiconductor material on which a semiconductor integration process can be performed. The substrate 101 may be doped with an n-type or p-type dopant. In an embodiment, the substrate 101 may be a silicon (Si) substrate doped with a p-type dopant.

The switching transistor structure MTD includes a switching gate dielectric layer 110 disposed on the substrate 101, and a switching gate electrode layer 120 disposed on the switching gate dielectric layer 110. The switching transistor structure MTD includes a switching source electrode 101a and a switching drain electrode 101b that are disposed in the substrate 101, and spaced apart from each other. In an embodiment, when the substrate 101 is doped with a p-type dopant, the switching source electrode 101a and the switching drain electrode 101b may be regions of the substrate 101, doped with an n-type dopant.

The switching gate dielectric layer 110 may include a non-ferroelectric material. As an example, the switching gate dielectric layer 110 may include a paraelectric material. The switching gate dielectric layer 110 may include, for example, oxide, nitride, oxynitride, or a combination of two or more thereof. In an embodiment, the switching gate dielectric layer 110 may include a low-k material having a low dielectric constant. As an example, the low-k material may include silicon oxide, silicon nitride, silicon oxynitride, or a combination of two or more thereof. In another embodiment, the switching gate dielectric layer 110 may include a high-k material having a high dielectric constant. The high-k material may include, for example, aluminum oxide, hafnium oxide, or a combination thereof.

The switching gate dielectric layer 110 may correspond to the switching gate dielectric layer GD1 of the switching transistor MT in FIG. 3. The switching gate dielectric layer 110 is disposed between the substrate 101 and the switching gate electrode layer 120 to form a non-ferroelectric capacitor. The switching gate dielectric layer 110 has a predetermined first width w110 in the x-direction.

The switching gate electrode layer 120 may include a conductive material. The conductive material may include, for example, doped semiconductor, metal, conductive metal nitride, conductive metal carbide, conductive metal silicide, or conductive metal oxide. The conductive material may include, for example, silicon (Si) doped with an n-type or p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

A hard mask layer 130 is disposed on the switching gate electrode layer 120. The hard mask layer 130 may include oxide, nitride, oxynitride, or a combination thereof. A first interlayer insulation layer 510 is disposed in a lateral direction (for example, the x-direction) of the switching gate dielectric layer 110, the switching gate electrode layer 120, and the hard mask layer 130. A second interlayer insulation layer 520 is disposed on the hard mask layer 130 and the first interlayer insulation layer 510.

Referring to FIG. 4 again, the ferroelectric capacitor structure FED is disposed on the second interlayer insulation layer 520. The ferroelectric capacitor structure FED includes a first memory electrode layer 160 disposed on the second interlayer insulation layer 520, a ferroelectric memory layer 170 disposed on the first memory electrode layer 160, and a second memory electrode layer 180 disposed on the ferroelectric memory layer 170. The ferroelectric capacitor structure FED is buried by a third interlayer insulation layer 530 disposed on the second interlayer insulation layer 520.

A memory connection plug 141 is disposed between the switching gate electrode layer 120 of the switching transistor structure MTD and the first memory electrode layer 160 of the ferroelectric capacitor structure FED. The memory connection plug 141 is disposed to penetrate the hard mask layer 130 and the second interlayer insulation layer 520 to reach the first memory electrode layer 160 on the switching gate electrode layer 120. The memory connection plug 141 may electrically connect the switching gate electrode layer 120 to the first memory electrode layer 160.

The memory connection plug 141 may include a conductive material. The conductive material may include, for example, metal, conductive metal nitride, conductive metal carbide, conductive metal silicide, conductive metal oxide, or a combination of two or more thereof.

Each of the first memory electrode layer 160 and the second memory electrode layer 180 may include a conductive material. The conductive material may include, for example, metal, conductive metal nitride, conductive metal carbide, conductive metal silicide, or conductive metal oxide. The conductive material may include, for example, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The ferroelectric memory layer 170 may include a ferroelectric material. The ferroelectric material may include, for example, hafnium oxide, zirconium oxide, hafnium zirconium oxide, or a combination of two or more thereof. The ferroelectric memory layer 170 may have a pair of remanent polarization states with different orientations. The remanent polarization may be switched to have different orientations when a switching voltage equal to or higher than a predetermined threshold voltage is applied between the first memory electrode layer 160 and the second memory electrode layer 180.

The ferroelectric memory layer 170 may correspond to the ferroelectric layer GD2 of the ferroelectric capacitor FE in FIG. 3. The ferroelectric memory layer 170 is disposed between the first memory electrode layer 160 and the second memory electrode layer 180 to form the ferroelectric capacitor structure FED. The ferroelectric memory layer 170 has a predetermined second width w170 in the x-direction.

Referring to FIG. 4 again, the ferroelectric capacitor structure FED including the ferroelectric memory layer 170 and the non-ferroelectric capacitor including the switching gate dielectric layer 110 may be electrically connected in series between the substrate 101 and the second memory electrode layer 180. In this case, a surface area of the ferroelectric memory layer 170 constituting the ferroelectric capacitor structure FED may be controlled to be less than a surface area of the switching gate dielectric layer 110 constituting the non- ferroelectric capacitor. As an example, the second width w170 of the ferroelectric memory layer 170 may be less than the first width w110 of the switching gate dielectric layer 110.

Accordingly, as described with reference to FIG. 2C, in the circuit configuration in which the ferroelectric capacitor structure FED and the non-ferroelectric capacitor are connected in series to each other, the ratio C₁₇₀/C₁₁₀ can be reduced. Here, C₁₇₀ may be capacitance of the ferroelectric memory layer 170 and C₁₁₀ may be capacitance of the switching gate dielectric layer 110. Through this, the ratio V₁₁₀/V₁₇₀ is reduced, and thus, the voltage distributed to the switching gate dielectric layer 110 can be reduced compared to the voltage distributed to the ferroelectric memory layer 170 during the program operation and erase operation. As a result, the breakdown phenomenon of the switching gate dielectric layer 110 can be alleviated.

Referring to FIG. 4, a switching source contact 143 penetrating the first interlayer insulation layer 510 to be electrically connected to the switching source electrode 101a is disposed on the substrate 101. In addition, a bit line 152 is disposed to be electrically connected to the switching source contact 143 on the first interlayer insulation layer 510. A switching drain contact 144 penetrating the first interlayer insulation layer 510 to be electrically connected to the switching drain electrode 101b is disposed on the substrate 101. In addition, a source line is disposed electrically connected to the switching drain contact 144 on the first interlayer insulation layer 510.

Referring to FIG. 4, the control transistor structure CTD is disposed on the substrate 101. The control transistor structure CTD includes a control source electrode 101c and a control drain electrode 101d that are disposed in the substrate 101, and spaced apart from each other. In an embodiment, when the substrate 101 is doped with a p-type dopant, the control source electrode 101c and the control drain electrode 101d may be regions of the substrate 101, doped with an n-type dopant. In another embodiment, the control source electrode 101c and the control drain electrode 101d may be conductive layers filling trenches that are formed spaced apart from each other in the substrate 101.

The control transistor structure CTD includes a control gate dielectric layer 210 and a control gate electrode layer 220 that are disposed on a region of the substrate 101, located between the control source electrode 101c and the control drain electrode 101d. The control transistor structure CTD includes a hard mask layer 230 disposed on the control gate electrode layer 220.

The control gate dielectric layer 210 may include a non-ferroelectric material. As an example, the control gate dielectric layer 210 may include a paraelectric material. The control gate dielectric layer 210 may include, for example, oxide, nitride, oxynitride, or a combination of two or more thereof. The control gate dielectric layer 210 may correspond to the control gate dielectric layer GD3 of the control transistor CT in FIG. 3.

The control gate electrode layer 220 may include a conductive material. The conductive material may include, for example, doped semiconductor, metal, conductive metal nitride, conductive metal carbide, conductive metal silicide, or conductive metal oxide. The control gate electrode layer 220 may correspond to the control gate electrode Gc of the control transistor CT in FIG. 3. The hard mask layer 230 may include oxide, nitride, oxynitride, or a combination of two or more thereof.

Referring to FIG. 4, the control source electrode 101c of the control transistor structure CTD is electrically connected to a control word line 252 through a control source contact 242. The control source contact 242 is disposed in the form of a plug inside the first interlayer insulation layer 510 and is disposed to contact the control source electrode 101c. The control word line 252 is disposed in the form of a line pattern on the first interlayer insulation layer 510 and is disposed to overlap the control source contact 242 in the z-direction.

According to an embodiment of the present disclosure, the control drain electrode 101d of the control transistor structure CTD is electrically connected to the switching gate electrode layer 120 of the switching transistor structure MTD through a control connection structure 243, 244, and 245. The control connection structure 243, 244, and 245 include a control drain contact 243, a control interconnection layer 244, and a control connection plug 245.

In an embodiment, the control drain contact 243 is disposed in the form of a plug inside the first interlayer insulation layer 510 and extends from the control drain electrode 101d to the control interconnection layer 244. The control interconnection layer 244 is disposed on the first interlayer insulation layer 510 and disposed to contact the control drain contact 243 and the control connection plug 245. That is, the control interconnection layer 244 is disposed to overlap the control drain contact 243 and the control connection plug 245 in the z-direction. The control connection plug 245 is disposed spaced apart from the memory connection plug 141 on the switching gate electrode layer 120. The control connection plug 245 is disposed in the form of a plug inside the hard mask layer 130, and extends from the switching gate electrode layer 120 to the control interconnection layer 244.

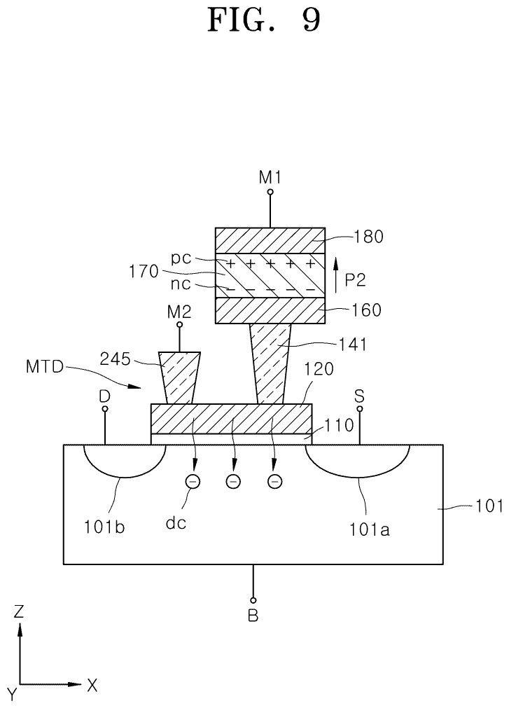

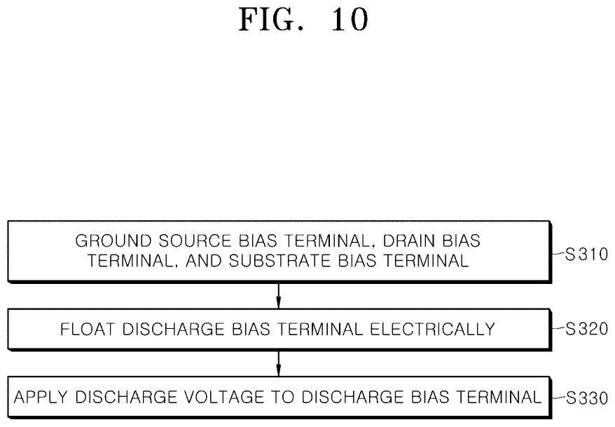

When a gate voltage of a predetermined threshold voltage or higher to the control gate electrode layer 220, the control transistor structure CTD is electrically turned on. In this case, a control voltage provided from the control word line 252 to the control source electrode 101c may be transferred to the switching gate electrode layer 120 of the switching transistor structure MTD through the control drain electrode 101d and the control connection structure 243, 244, and 245. As a result, the discharge operation of the semiconductor device 1 described later with reference to FIG. 9 and FIG. 10 may proceed.

Referring to FIG. 4, the selection transistor structure STD is disposed on the substrate 101. The selection transistor structure STD includes a selection source electrode 101e and a selection drain electrode 101f that are disposed in the substrate 101, and spaced apart from each other. In an embodiment, when the substrate 101 is doped with a p-type dopant, the selection source electrode 101e and the selection drain electrode 101f may be regions of the substrate 101, doped with an n-type dopant. In another embodiment, the selection source electrode 101e and the selection drain electrode 101f may be conductive layers filling trenches that are formed spaced apart from each other in the substrate 101.

The selection transistor structure STD includes a selection gate dielectric layer 310 and a selection gate electrode layer 320 that are disposed on a region of the substrate 101, located between the selection source electrode 101e and the selection drain electrode 101f. The selection transistor structure STD includes a hard mask layer 330 disposed on the selection gate electrode 320. The selection gate dielectric layer 310, the selection gate electrode layer 320, and the hard mask layer 330 of the selection transistor structure STD may have substantially the same configurations as the control gate dielectric layer 210, the control gate electrode layer 220, and the hard mask layer 230 of the control transistor structure CTD, respectively.

Referring to FIG. 4, the selection source electrode 101e of the selection transistor structure STD is electrically connected to a selection word line 352 through a selection source contact 342. The selection source contact 342 is disposed in the form of a plug inside the first interlayer insulation layer 510 and disposed to contact the selection source electrode 101e and the selection word line 352. The selection word line 352 is disposed in the form of a line pattern on the first interlayer insulation layer 510 and disposed to overlap the selection source contact 342 in the z-direction.

According to an embodiment of the present disclosure, the selection drain electrode 101f of the selection transistor structure STD is electrically connected to the second memory electrode layer 180 of the ferroelectric capacitor structure FED through a selection connection structure 343, 344, and 345. The selection connection structure 343, 344, and 345 includes a selection drain contact 343, a selection interconnection layer 344, and a selection connection plug 345.

In an embodiment, the selection drain contact 343 is disposed in the form of a plug inside the first interlayer insulation layer 510, the second interlayer insulation layer 520, and the third interlayer insulation layer 530, and extends from the selection drain electrode 101f to the selection interconnection layer 344. The selection interconnection layer 344 is disposed on the third interlayer insulation layer 530. The selection interconnection layer 344 is disposed to contact the selection drain contact 343 and the selection connection plug 345. That is, the selection interconnection layer 344 is disposed to overlap with the selection drain contact 343 and the selection connection plug 345 in the z-direction. The selection connection plug 345 is disposed in the form of a plug inside the third interlayer insulation layer 530 and extends from the second memory electrode layer 180 to the selection interconnection layer 344.

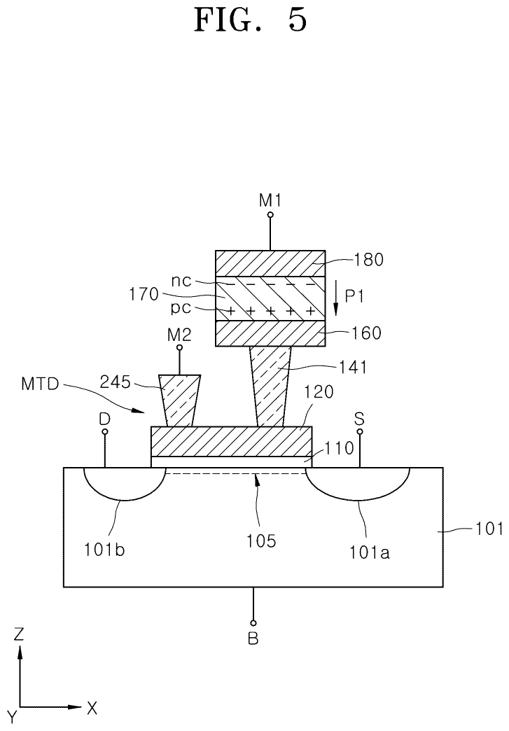

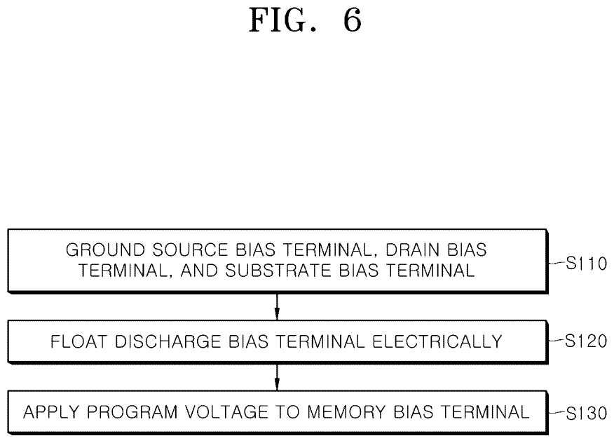

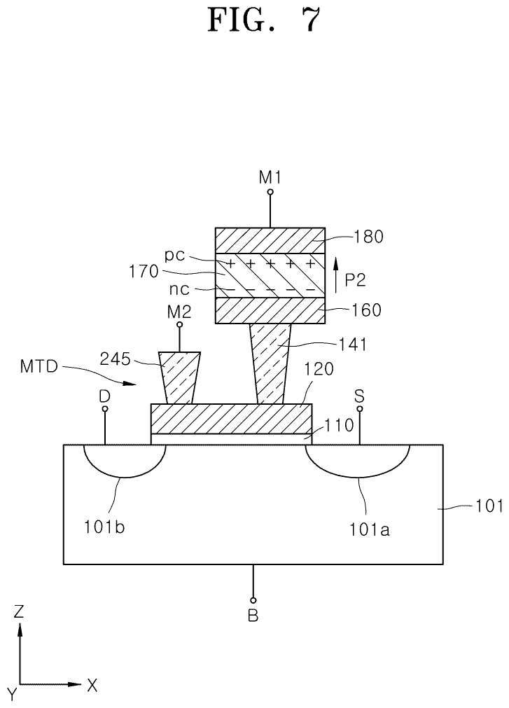

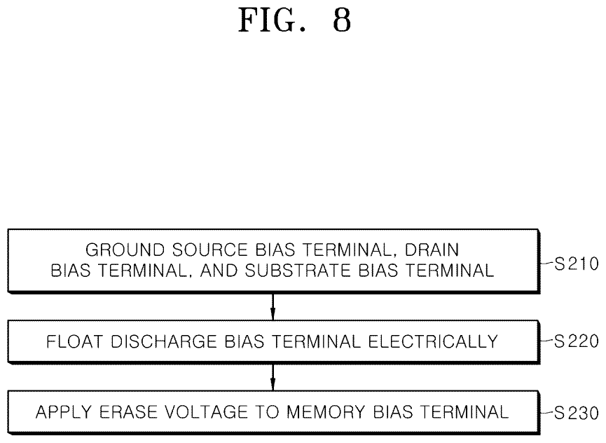

When a gate voltage of a predetermined threshold voltage or higher is applied to the selection gate electrode layer 320, the selection transistor structure STD is turned on. In this case, the selection voltage provided from the selection word line 352 to the selection source electrode 101e may be transmitted to the second memory electrode layer 180 of the ferroelectric capacitor structure FED through the selection drain electrode 101f and the selection connection structure 343, 344, and 345. The selection voltage may be, for example, a program voltage, an erase voltage, or a read voltage. As a result, a program operation described later with reference to FIG. 5 and FIG. 6 or an erase operation or a read operation described later with reference to FIG. 7 and FIG. 8 may be performed.

Referring to FIG. 4, a doped well region 101g for applying a substrate voltage (i.e., body bias or bulk bias) to the substrate 101 is disposed in the substrate 101. When the substrate 101 is doped with a p-type dopant, the doped well region 101g may be a region doped with a p-type dopant at a higher doping concentration than the substrate 101. The doped well region 101g may receive the substrate voltage from a substrate voltage line 452 through a contact plug 442. The substrate voltage line 452 is disposed on the first interlayer insulation layer 510. The contact plug 442 is disposed inside the first interlayer insulation layer 510 and extends from the doped well region 101g to the substrate voltage line 452.

FIG. 5 is a schematic diagram illustrating a program operation according to an embodiment of the present disclosure. FIG. 6 is a schematic flowchart illustrating the program operation according to an embodiment of the present disclosure.

The program operation of FIG. 5 and FIG. 6 can be described using the semiconductor device 1 in FIG. 4. In FIG. 5, the illustration of the selection transistor structure STD and the control transistor structure CTD of the semiconductor device 1 of FIG. 4 is omitted for convenience of description. Instead of the selection transistor structure STD, a memory bias terminal M1 is connected to the second memory electrode layer 180. Additionally, instead of the control transistor structure CTD, a discharge bias terminal M2 is connected to the switching gate electrode layer 120. A substrate bias terminal B is connected to the substrate 101. The substrate bias terminal B may apply the substrate voltage to the substrate 101. A source bias terminal S and a drain bias terminal D that are connected to the bit line and the source line, respectively, are connected to the switching source electrode layer 101a and the switching drain electrode layer 101b, respectively.

Referring to S110 in FIG. 6, the source bias terminal S, the drain bias terminal D, and the substrate bias terminal B of the semiconductor device (1 of FIG. 4) are grounded. Referring to S120 in FIG. 6, the control transistor structure CTD of FIG. 4, which is electrically connected to the control connection plug 245, is electrically turned off and the discharge bias terminal M2 is electrically floated. As the discharge bias terminal M2 is floated, the switching gate electrode layer 120 may be electrically floated.

Referring to S130 in FIG. 6, a program voltage is applied to the memory bias terminal M1 to write first polarization P1 in the ferroelectric memory layer 170. The program voltage may be applied as a bias having a positive polarity. The program voltage is applied between the substrate 101 and the second memory electrode layer 180 while the switching gate electrode layer 120 is electrically floated. For convenience, the first polarization P1 written by the program voltage is depicted as an arrow pointing from the second memory electrode layer 180 to the first memory electrode layer 160. By the first polarization P1, positive charges pc may be induced in a region of the ferroelectric memory layer 170, adjacent to the first memory electrode layer 160, and negative charges nc may be induced in a region of the ferroelectric memory layer 170, adjacent to the second memory electrode layer 180.

Subsequently, after the program voltage is removed, first remanent polarization having the same orientation as the first polarization P1 may be formed within the ferroelectric memory layer 170. The first remanent polarization may maintain the positive charges pc and the negative charges nc of the above-described arrangement within the ferroelectric memory layer 170. The positive charges pc distributed within the ferroelectric memory layer 170 adjacent to the first memory electrode layer 160 may induce electrons in the channel region 105 of the substrate 101, thereby reducing the magnitude of the switching threshold voltage of the switching transistor MTD. In conclusion, by the program operation, first signal information corresponding to the first remanent polarization can be stored in the ferroelectric memory layer 170.

FIG. 7 is a schematic diagram illustrating an erase operation according to an embodiment of the present disclosure. FIG. 8 a schematic flowchart illustrating the erase operation according to an embodiment of the present disclosure.

The erase operation of FIG. 7 and FIG. 8 can be described using the semiconductor device 1 in FIG. 4. In FIG. 7, for convenience of description, a memory bias terminal M1 and a discharge bias terminal M2 are illustrated instead of the selection transistor structure STD and the control transistor structure CTD, respectively. A substrate bias terminal B, a source bias terminal S, and a drain bias terminal D are connected to the substrate 101, the switching source electrode layer 101a, and the switching drain electrode layer 101b, respectively.

Referring to S210 in FIG. 8, the source bias terminal S, the drain bias terminal D, and the substrate bias terminal B of the semiconductor device (1 of FIG. 4) are grounded. Referring to S220 in FIG. 8, the control transistor structure CTD of FIG. 4, which is electrically connected to the control connection plug 245, is turned off and the discharge bias terminal M2 is electrically floated. As the discharge bias terminal M2 is floated, the switching gate electrode layer 120 may be electrically floated.

Referring to S230 in FIG. 8, an erase voltage is applied to the memory bias terminal M1 to write second polarization P2 in the ferroelectric memory layer 170. The erase voltage may be applied as a bias having a negative polarity. The erase voltage is applied between the substrate 101 and the second memory electrode layer 180 while the switching gate electrode layer 120 is electrically floated. For convenience, the second polarization P2 switched by the erase voltage is depicted as an arrow pointing from the first memory electrode layer 160 to the second memory electrode layer 180. By the second polarization P2, negative charges nc may be induced in the region of the ferroelectric memory layer 170, adjacent to the first memory electrode layer 160, and positive charges pc may be induced in the region of the ferroelectric memory layer 170, adjacent to the second memory electrode layer 180.

Subsequently, after the erase voltage is removed, second remanent polarization having the same orientation as the second polarization P2 may be formed within the ferroelectric memory layer 170. The second remanent polarization can maintain the positive charges pc and the negative charges nc of the above-described arrangement within the ferroelectric memory layer 170. The negative charges nc distributed within the ferroelectric memory layer 170, adjacent to the first memory electrode layer 160 may expel electrons from the channel region 105 of the substrate 101, thereby increasing the switching threshold voltage of the switching transistor MTD.

In conclusion, by the erasing operation, second signal information corresponding to the second remanent polarization can be stored in the ferroelectric memory layer 170.

FIG. 9 is a schematic diagram illustrating a discharge operation according to an embodiment of the present disclosure. FIG. 10 is a schematic flowchart illustrating the discharge operation according to an embodiment of the present disclosure.

While the above-described program operation and erase operation are repeated, electrons can be charged in the switching gate electrode layer 120 which is in a floating state. As described above, the electrons charged in the switching gate electrode layer 120 may be due to electrons leaking from the ferroelectric memory layer 170.

The discharge operation of FIG. 9 and FIG. 10 can be described using the semiconductor device 1 in FIG. 4. In FIG. 9, for convenience of description, a memory bias terminal M1 and a discharge bias terminal M2 are illustrated instead of the selection transistor structure STD and the control transistor structure CTD, respectively. A substrate bias terminal B, a source bias terminal S, and a drain bias terminal D are connected to the substrate 101, the switching source electrode layer 101a, and the switching drain electrode layer 101b, respectively.

Referring to S310 in FIG. 10, the source bias terminal S, the drain bias terminal D, and the substrate bias terminal B are grounded. Referring to S320 in FIG. 10, the selection transistor structure STD in FIG. 4 electrically connected to the second memory electrode layer 180 is turned off and the memory bias terminal M1 is electrically floated. In this case, the first remanent polarization or the second remanent polarization may be maintained within the second memory electrode layer 180. In FIG. 9, for convenience, the second remanent polarization having the orientation of the second polarization is illustrated.

Referring to S330 in FIG. 10, a discharge voltage is applied to the discharge bias terminal M2 to discharge the electrons dc charged in the switching gate electrode layer 170 to the substrate 101. The discharge voltage may be applied as a bias having a negative polarity. By the discharge voltage, the electrons dc may tunnel to the substrate 101 through the switching gate dielectric layer 110.

By removing the electrons charged in the switching gate electrode layer 120 through the discharge operation, the potential of the switching gate electrode layer 120 can be maintained at a certain level. Accordingly, the reliability of the channel threshold voltage of the switching transistor structure MTD can be improved while the program operation and erase operation of the semiconductor device 1 are repeated.

Embodiments of the present disclosure have been disclosed for illustrative purposes. Those skilled in the art will appreciate that various modifications, additions and substitutions are possible, without departing from the scope and spirit of the present disclosure and the accompanying claims. Furthermore, the embodiments may be combined to form additional embodiments.

What is claimed is:

1. A semiconductor device comprising a ferroelectric memory structure, a control transistor structure, and a control connection structure that electrically connects the control transistor with the ferroelectric memory structure,
wherein the ferroelectric memory structure comprises:
a switching gate dielectric layer disposed on a substrate;
a switching gate electrode layer disposed on the switching gate dielectric layer; and
a first memory electrode layer, a ferroelectric memory layer, and a second memory electrode layer that are disposed over the switching gate electrode layer, the first memory electrode layer being electrically connected to the switching gate electrode layer,
wherein the control transistor structure comprises:
a control source electrode and a control drain electrode that are disposed in the substrate, the control source electrode and the control drain electrode spaced apart from each other; and
a control gate dielectric layer and a control gate electrode layer that are disposed on a first region of the substrate, the first region being located between the control source electrode and the control drain electrode, and
wherein the control connection structure electrically connects the control drain electrode and the switching gate electrode layer to each other over the substrate.

2. The semiconductor device of claim 1, further comprising a memory connection plug disposed on the switching gate electrode layer to electrically connect the switching gate electrode layer and the first memory electrode layer.

3. The semiconductor device of claim 2, wherein the control connection structure further comprises:
a control connection plug disposed on the switching gate electrode layer spaced apart from the memory connection plug;
a control interconnection layer disposed over the substrate to contact the control connection plug; and
a control drain contact connecting the control drain electrode and the control interconnection layer.

4. The semiconductor device of claim 1,
wherein the ferroelectric memory structure further comprises a switching source electrode and a switching drain electrode that are disposed in the substrate,
wherein the switching source electrode and the switching drain electrode are spaced apart from each other, and
wherein the switching source electrode is electrically connected to a bit line, and the switching drain electrode is electrically connected to a source line.

5. The semiconductor device of claim 1, wherein the ferroelectric memory layer has remanent polarization states with different orientations.

6. The semiconductor device of claim 5, wherein the ferroelectric memory layer comprises at least one of hafnium oxide, zirconium oxide, and hafnium zirconium oxide.

7. The semiconductor device of claim 1, further comprising a control word line disposed over the substrate, the control word line providing a control voltage to the control source electrode.

8. The semiconductor device of claim 1, further comprising a selection transistor structure electrically connected to the ferroelectric memory structure through a selection connection structure,
wherein the selection transistor structure comprises:
a selection source electrode and a selection drain electrode that are disposed in the substrate, the selection source electrode and the selection drain electrode spaced apart from each other; and
a selection gate dielectric layer and a selection gate electrode layer that are disposed on a second region of the substrate, the second region being located between the selection source electrode and the selection drain electrode, and
wherein the selection connection structure electrically connects the selection drain electrode and the second memory electrode layer to each other.

9. The semiconductor device of claim 8,
wherein the selection connection structure comprises:
a selection interconnection layer disposed over the substrate;
a selection connection plug connecting the second memory electrode layer and the selection interconnection layer; and
a selection drain contact connecting the selection drain electrode and the selection interconnection layer.

10. The semiconductor device of claim 8,
wherein the selection transistor structure is configured to be electrically turned on while the control transistor structure is electrically turned off, and
wherein the control transistor structure is configured to be electrically turned on while the selection transistor structure is electrically turned off.

11. The semiconductor device of claim 1, further comprising a doped well region disposed in the substrate, the doped well region applying a substrate voltage to the substrate.

12. A semiconductor device comprising:
a ferroelectric memory structure disposed over a substrate; and
a control transistor structure and a selection transistor structure that are disposed on the substrate and electrically connected to the ferroelectric memory structure,
wherein the ferroelectric memory structure comprises:
a switching gate dielectric layer disposed on the substrate;
a switching gate electrode layer disposed on the switching gate dielectric layer; and
a first memory electrode layer, a ferroelectric memory layer, and a second memory electrode layer that are disposed over the switching gate electrode layer, the first memory electrode layer being electrically connected to the switching gate electrode layer,
wherein the control transistor structure comprises a control drain electrode electrically connected to the switching gate electrode layer and a control source electrode receiving a control voltage,
wherein the selection transistor structure comprises a selection drain electrode electrically connected to the second memory electrode layer and a selection source electrode receiving a selection voltage, and
wherein the control transistor structure is configured to be electrically turned on while the selection transistor structure is electrically turned off, and the selection transistor structure is configured to be electrically turned on while the control transistor structure is electrically turned off.

13. The semiconductor device of claim 12, further comprising a memory connection plug disposed on the switching gate electrode layer.

14. The semiconductor device of claim 13, further comprising a control connection structure electrically connecting the switching gate electrode layer and the control drain electrode,
wherein the control connection structure comprises:
a control connection plug disposed on the switching gate electrode layer spaced apart from the memory connection plug;
a control interconnection layer disposed over the substrate to contact the control connection plug; and
a control drain contact connecting the control drain electrode and the control interconnection layer.

15. The semiconductor device of claim 12, further comprising a selection connection structure electrically connecting the selection drain electrode and the second memory electrode layer,
wherein the selection connection structure comprises:
a selection interconnection layer disposed over the substrate;
a selection connection plug connecting the second memory electrode layer and the selection interconnection layer; and
a selection drain contact connecting the selection drain electrode and the selection interconnection layer.

16. The semiconductor device of claim 12, further comprising a doped well region disposed in the substrate, the doped well region applying a substrate voltage to the substrate.

17. A method of driving a semiconductor device, the method comprising:
preparing a semiconductor device including a ferroelectric memory structure, the ferroelectric memory structure comprising a switching gate dielectric layer disposed on a substrate, a switching gate electrode layer disposed on the switching gate dielectric layer,, a first memory electrode layer disposed over the switching gate electrode layer, a ferroelectric memory layer disposed on the first memory electrode layer, and a second memory electrode layer disposed on the ferroelectric memory layer, wherein the first memory electrode layer is electrically connected to the switching gate electrode layer, and wherein the switching gate electrode layer is electrically connected to a discharge bias terminal, the substrate is electrically connected to a substrate bias terminal, and the second memory electrode layer is electrically connected to a memory bias terminal;
electrically floating the discharge bias terminal to electrically float the switching gate electrode layer; and
applying a program voltage to the memory bias terminal to write polarization in the ferroelectric memory layer.

18. The method of claim 17, further comprising a control transistor structure electrically connected to the discharge bias terminal,
the control transistor structure comprises:
a control source electrode and a control drain electrode that are disposed spaced apart from each other in the substrate; and
a control gate dielectric layer and a control gate electrode layer that are disposed on a region of the substrate, the region located between the control source electrode and the control drain electrode, wherein the control connection plug is electrically connected to the control drain electrode.

19. The method of claim 17, further comprising:
electrically floating the memory bias terminal to electrically float the second memory electrode layer; and
applying a discharge voltage to the discharge bias terminal to discharge electrons charged in the switching gate electrode layer to the substrate.

20. The method of claim 19, wherein applying the discharge voltage comprises applying a voltage having a negative polarity to the switching gate electrode layer while the memory bias terminal is electrically floated.
